(19) United States
(12) Patent Application Publication
(10) Pub. No.: US 2015/0377934 A1
(43) Pub. Date: Dec. 31, 2015

(54) Energy Measuring Unit Compatible with Circuit Breaker in Distribution Board

(71) Applicant: Encored Technologies, Inc., Seoul (KR)

(72) Inventors: Jongwoong Choe, Seoul (KR); Park Jiho, Seoul (KR); Hyunsu Bae, Seoul (KR)

(73) Assignee: ENCORED TECHNOLOGIES, INC., Seoul (KR)

(21) Appl. No.: 14/747,290

(22) Filed: Jun. 23, 2015

(30) Foreign Application Priority Data
Jun. 26, 2014 (KR) 10-2014-0078859

(51) Int. Cl. G01R 19/25; H02B 1/44; H02B 1/20; G01R 21/06

(52) U.S. Cl. CPC G01R 19/2513; G01R 21/06; H02B 1/44; H02B 1/20

(57) ABSTRACT

Embodiments herein provide an energy measuring unit, compatible with a circuit breaker in a distribution board, for measuring energy usage information. The energy measuring unit includes a voltage input terminal, and a voltage measuring unit electrically, connected to the voltage input terminal, configured to measure a voltage value. The energy measuring unit measures energy usage information using the voltage value. Further, the energy measuring unit includes a communication unit configured to communicate the energy usage information to a remote electronic device. In an embodiment, the voltage input terminal is configured to fix the energy measuring unit to the distribution board to receive voltage from a busbar of the distribution board. The energy measuring unit is configured to be compatible with a branch circuit breaker coupled with the busbar of the distribution board.

### TECHNICAL FIELD

The present invention relates to an energy measuring system, and more particularly, to energy measuring unit installed in a household distribution board.

### BACKGROUND

Techniques that monitor power consumption or usage habit of individual households through a computer or a smart phone are actively developed. In particular, techniques that monitor electric energy through connection devices such as an Internet network, Bluetooth, Zigbee, or the like are actively developed. The techniques require connecting an electric power measuring device and a communication device of a user.

Existing devices, such as a mechanical or electronic power meter, that measure household power consumption, are mostly installed on a wall surface of a building. As complicated wiring such as a communication line, a power line, and the like are required to connect a separate communication device to the existing measuring device, it's difficult for a user to directly install the complicated wiring.

In order to solve the problem, devices that couple a voltage measuring device to a household socket and communicate with the computer through a serial port are developed. As the measuring device coupled to a socket measures only voltage, a separate current measuring sensor is required. Further, as the current measuring sensor needs to be installed around the distribution board (which is a place separated from the voltage measuring device), there is inconvenience in exchanging a battery in the current measuring sensor which is using the battery as a power source of the current measuring sensor.

In a conventional mechanism, a current sensor separated from a body of the energy measuring unit is installed in the distribution board or on a specific power line. In addition, a current value is measured by using wireless communication between the current sensor and the body of the energy measuring unit. It is also advantageous that the body of the energy measuring unit can be positioned at any position desired by a user, but there is inconvenience that a battery needs to be used to supply power required for the current sensor. When a battery capacity is increased so as to increase a battery replacement cycle, the overall product cost gets increased and a spatial restriction occurs in terms of installation of the current measurement module due to an increase in size of the product.

In another conventional mechanism, the current sensor is installed in the distribution board or on the specific power line and the body of the energy measuring unit is installed outside the distribution board. Further, the current sensor and the body of the energy measuring unit are connected with each other by a wired method. In this case, there is a problem in aesthetics due to a long electric wire for connecting the current sensor and the body of the energy measuring unit. Further, since a general distribution board does not provide a hole for connecting the electric wire, the distribution board needs to be additionally processed. Additional construction for fixing a measurement device to a position adjacent to a household distribution board is required due to a restriction of the length of the electric wire between the current measuring module and the measurement device.

In yet another conventional mechanism, the current sensor is installed in the distribution board or on the specific power line and the body of the energy measuring unit is installed inside the distribution board and thereafter, the current sensor and the body of the energy measuring unit are connected with each other by the wired method. However, unlike the present invention, a separate wire for power connection is used without fixing the energy measuring unit by using the busbar. In this case, an available space in the distribution board may not be secured. As a result, it is impossible to mount the energy measuring unit due to a restriction of an installation space in some cases. Further, a wireless communication antenna connecting the energy measuring unit and an external monitoring device is not preferably constructed according to a shape of an internal space of the distribution board. In particular, when a wireless communication antenna part of the energy measuring unit faces a wall direction of a building, there is a problem in deterioration of communication sensitivity.

Furthermore, a power measuring device is installed in the distribution board together with the communication device, but it is difficult to use the power measuring device due to narrowness of an internal space, a difficulty in fixing work, and the like. For example, Korean Patent No. 10-1295843 proposes a device that mounts a sensor module which is detachable for each of an individual circuit breaker in the distribution board and transmits collected power consumption information to a monitoring device through wired or wireless communication. However, the sensor modules are mounted on the respective circuit breakers and connected by the complicated wirings. As a result, when the internal space of the distribution board is narrow, it is difficult to install the power measuring device. Further, even when a simple operation for the power measuring device or power information (such as a simple voltage value, and the like) is intended to be determined, it is disadvantageous as the collected power information or a status of the device may not be determined without a separate monitoring device.

The above information is presented as background information only to help the reader to understand the present invention. Applicants have made no determination and make no assertion as to whether any of the above might be applicable as Prior Art with regard to the present invention.

### SUMMARY OF INVENTION

The present invention provides an energy measuring unit which can be easily installed without additional space securing or additional wiring in a distribution board and can communicate with an external monitoring device. The energy measuring unit described herein can intuitively recognize status information or measurement information without a separate external monitoring device thereby reducing a wireless communication failure condition.

Accordingly the embodiments herein provide an energy measuring unit for measuring energy usage information. The energy measuring unit includes a voltage input terminal, and a voltage measuring unit electrically, connected to the voltage input terminal, configured to measure a voltage value. The energy measuring unit measures energy usage information using the voltage value. Further, the energy measuring unit includes a communication unit configured to communicate the energy usage information to a remote electronic device. In an embodiment, the voltage input terminal is configured to fix the energy measuring unit to a distribution board to receive voltage from a busbar of the distribution board. The energy measuring unit is configured to be compatible with a branch circuit breaker coupled with the busbar of the distribution board.

In an embodiment, the energy measuring unit further comprises a current measuring module, connected to the energy measuring unit, configured to measure a current value. The energy measuring unit is configured to measure the energy usage information using the voltage value and the current value.

In an embodiment, the energy measuring unit further comprises a display unit configured to display at least one of the voltage value, the current value, the energy usage information and a status of the energy measuring unit. In an embodiment, the display unit corresponds to at least a part of a previously formed exposed portion of the distribution board.

In an embodiment, the energy measuring unit further comprises control switch unit configured to control the energy measuring unit. In an embodiment, the control switch unit corresponds to at least a part of a previously formed exposed portion of the distribution board.

In an embodiment, the communication unit includes a wireless communication antenna. In an embodiment, the wireless communication antenna is installed without facing a wall on which the distribution board is installed.

In an embodiment, the wireless communication antenna is deployed in the energy measuring unit to avoid an influence of generation of an arc between the branch circuit breaker and the busbar.

In an embodiment, the energy measuring unit has substantially same width as the branch circuit breaker.

Accordingly the embodiments herein provide a distribution board for supplying electricity to household. The distribution board includes a main circuit breaker configured to cut off an electricity input in the household, and a branch circuit breaker receiving electricity from the main circuit breaker to supply the electricity to a branch. Further, the distribution board includes busbar electrically connecting the main circuit breaker and the branch circuit breaker. Furthermore, the distribution board includes a distribution board cover protecting the distribution board, and an energy measuring unit configured to measure energy consumption supplied to the distribution board. In an embodiment, the energy measuring unit includes a voltage input terminal, and a voltage measuring unit, electrically connected with the voltage input terminal, to measure a voltage value. Further, the energy measuring unit includes an energy measuring unit configured to measure energy usage information using the voltage value, and a communication unit configured to communicate the energy usage information to a remote electronic device. In an embodiment, the voltage input terminal is configured to fix the energy measuring unit to the distribution board to receive voltage from the busbar. The energy measuring unit is configured to be compatible with the branch circuit breaker coupled with the busbar of the distribution board.

In an embodiment, the energy measuring unit is installed at a position having smallest energy consumption among positions at which the branch circuit breaker is installed.

In an embodiment, an output line of the busbar, connected to the energy measuring unit, is connected to a branch circuit breaker having second energy consumption in parallel.

In an embodiment, the distribution board further includes a control switch unit configured to control the energy measuring unit. In an embodiment the control switch unit corresponds to at least a part of a previously formed exposed portion of the distribution board.

In an embodiment, the communication unit comprises a wireless communication antenna. In an embodiment, the wireless communication antenna is installed without facing a wall on which the distribution board is installed.

In an embodiment, the wireless communication antenna is deployed in the energy measuring unit to avoid an influence of generation of an arc between the branch circuit breaker and the busbar. In an embodiment, energy measuring unit has substantially same width as the branch circuit breaker.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE FIGURES

This invention is illustrated in the accompanying drawings, throughout which like reference letters indicate corresponding parts in the various figures. The embodiments herein will be better understood from the following description with reference to the drawings, in which:

FIGS. 1a and 1b illustrate a distribution board on which an energy measuring unit compatible with a circuit breaker in a distribution board is mounted on a distribution board cover, according to embodiments as described herein;

FIG. 2 illustrates a configuration of the energy measuring unit compatible with the circuit breaker in the distribution board, according to embodiments as described herein; and

FIG. 3 illustrates an external configuration of the energy measuring unit compatible with the circuit breaker in the distribution board, according to embodiments as described herein.

### DETAILED DESCRIPTION OF INVENTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. Also, the various embodiments described herein are not necessarily mutually exclusive, as some embodiments can be combined with one or more other embodiments to form new embodiments. The term “or” as used herein, refers to a non-exclusive or, unless otherwise indicated. The examples used herein are intended merely to facilitate an understanding of ways in which the embodiments herein can be practiced and to further enable those skilled in the art to practice the embodiments herein. Accordingly, the examples should not be construed as limiting the scope of the embodiments herein.

Embodiments herein provide an energy measuring unit for measuring energy usage information. The energy measuring unit includes a voltage input terminal, and a voltage measuring unit electrically, connected to the voltage input terminal, configured to measure a voltage value. The energy measuring unit measures the energy usage information using the voltage value. Further, the energy measuring unit includes a communication unit configured to communicate the energy usage information to a remote electronic device. In an embodiment, the voltage input terminal is configured to fix the energy measuring unit to a distribution board to receive voltage from a busbar of the distribution board. The energy measuring unit is configured to be compatible with a branch circuit breaker coupled with the busbar of the distribution board.

Accordingly the embodiments herein provide a distribution board for supplying electricity to household. The distribution board includes a main circuit breaker configured to cut off an electricity input in the household, and a branch circuit breaker receiving electricity from the main circuit breaker to supply the electricity to a branch. Further, the distribution board includes busbar electrically connecting the main circuit breaker and the branch circuit breaker. Furthermore, the distribution board includes a distribution board cover protecting the distribution board, and an energy measuring unit configured to measure energy consumption supplied to the distribution board. In an embodiment, the energy measuring unit includes a voltage input terminal, and a voltage measuring unit, electrically connected with the voltage input terminal, to measure a voltage value. Further, the energy measuring unit includes an energy measuring unit configured to measure energy usage information using the voltage value, and a communication unit configured to communicate the energy usage information to a remote electronic device. In an embodiment, the voltage input terminal is configured to fix the energy measuring unit to the distribution board to receive voltage from the busbar. The energy measuring unit is configured to be compatible with the branch circuit breaker coupled with the busbar of the distribution board.

A simple and robust energy measuring unit is proposed which can be easily installed without additional space securing or additional wiring in a distribution board and can communicate with an external monitoring device. Further, a measuring unit is proposed that can intuitively recognize status information or measurement information of the energy measuring unit without a separate external monitoring device and reduces a wireless communication failure condition.

Unlike the conventional systems, the energy measuring unit which communicates with the remote electronic device can be easily installed without securing an additional internal space or additional wiring in the distribution board. In particular, fixation is easier than the conventional power measuring device and wiring is simplified using a busbar of the conventional distribution board for power connection.

Further, maintenance is convenient without exchanging a battery for the current measuring device and since there is no wire exposed to the outside of the distribution board, user's operational complexity can be resolved. In addition, a wireless communication failure is reduced and the need for a separate configuration such as an exterior antenna, or the like is thus reduced to drop a system configuration price. Therefore, installation of an energy measuring unit in each household is promoted to easily monitor usage of power energy in the household.

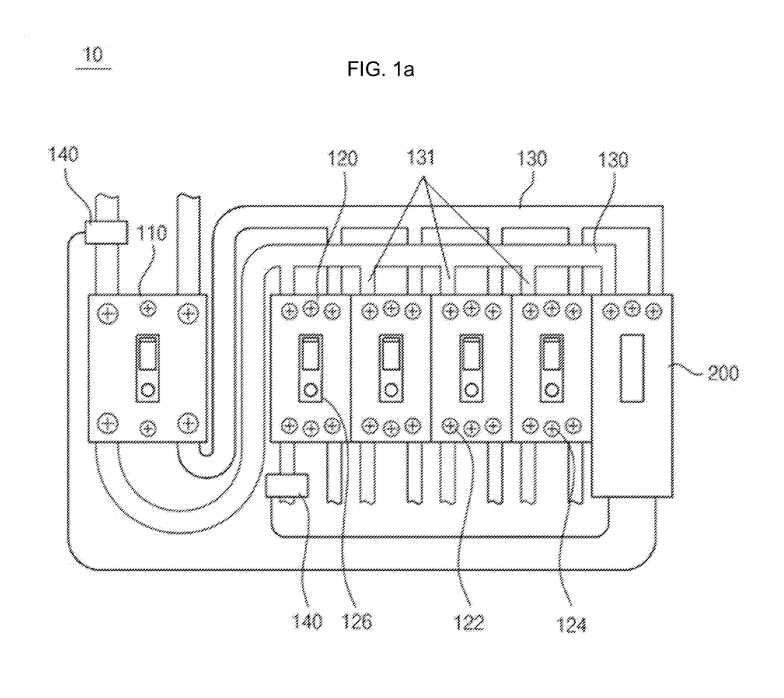

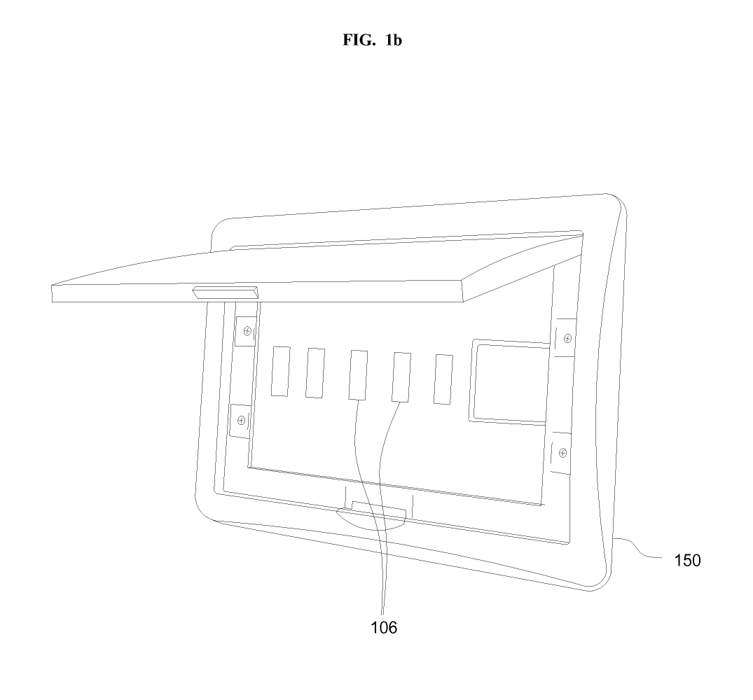

Referring now to the drawings and more particularly to FIGS. 1 to 3 where similar reference characters denote corresponding features consistently throughout the figures, there are shown preferred embodiments.

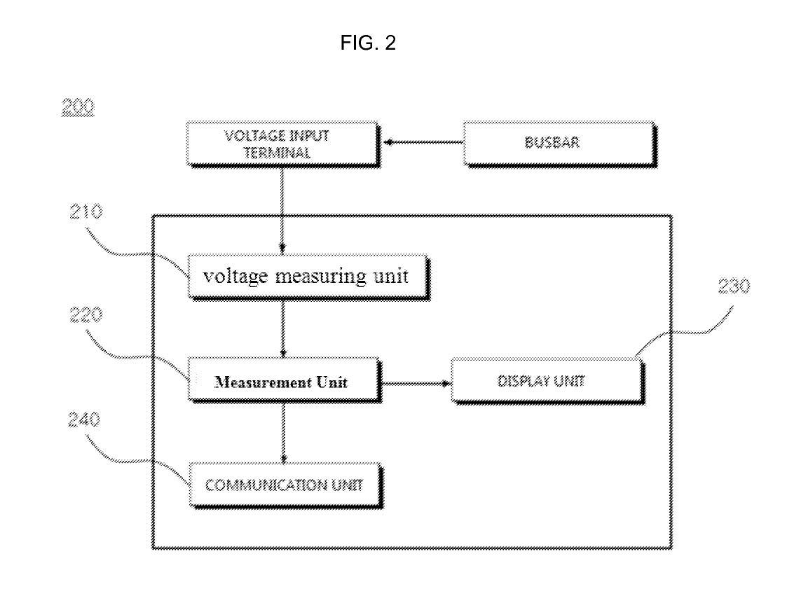

FIGS. 1a and 1b illustrate a distribution board 10, according to embodiments as described herein. In an embodiment, the distribution board 10 can be configured to include a main circuit breaker 110, a branch circuit breaker 120, a busbar 130, a distribution board cover 150, and an energy measuring unit 200. The branch circuit breaker 120 can be configured to include a switch unit 126. The energy measuring unit 200 can be configured to include a current measuring module 140, a voltage measuring unit 210, an energy measuring unit 200, a display unit 230, and a communication unit 240. The energy measuring unit 200 are described in detail in conjunction with the FIG. 2.

In the embodiment, the main circuit breaker 110 is installed in the distribution board 10 to cut off total power. The branch circuit breaker 120 is installed in the distribution board 10 and cuts off power supplied for each branch 131.

The busbar 130 is manufactured by using copper plate and is formed to include a plurality of branches 131 to be easily connected to fixation end 122 of a plurality of branch circuit breakers 120. In this case, the fixation end 122 of each branch circuit breaker 120 is electrically connected to the busbar 130 through each branch 131.

In an embodiment, voltage is applied to the branch circuit breaker 120 through the fixation end 122 for fixing the branch circuit breaker 120. However, the voltage may be applied through a metallic plate type terminal (not illustrated) attached onto a rear surface of the branch circuit breaker 120. In this case, the fixation end 122 includes a voltage applying metallic terminal.

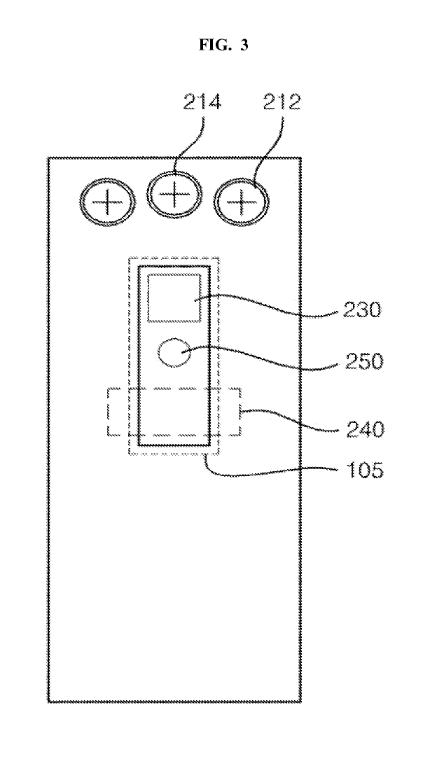

The energy measuring unit 200 is fixed and electrically connected to the branch 131 of the busbar 130 through a voltage input terminal 212 (see FIG. 3) of the energy measuring unit 200. The energy measuring unit 200 is fixed inside the distribution board 10 by a method which is substantially same as a method in which the branch circuit breaker 120 is installed in the distribution board 10. Herein, the term “substantially” has been used as a meaning including a case in which those skilled in the art may easily change a configuration. For example, a case in which those skilled in the art may electrically connect the energy measuring unit 200 with the branch of the busbar 130 using a metallic material other than a bolt.

In an embodiment, the energy measuring unit 200 has substantially the same width as the branch circuit breaker 120 installed in the distribution board 10 and is preferably fixed to a position corresponding to a position at which the branch circuit breaker 120 is installed.

In the embodiment, a bolt for fixing the energy measuring unit 200 is illustrated as the voltage input terminal 212. However, similarly to the branch circuit breaker 120, the metallic plate type terminal is additionally included in the rear surface (not illustrated) of the energy measuring unit 200 to be used as the voltage input terminal 212. In this case, the voltage input terminal 212 includes the bolt and the terminal of the energy measuring unit 200.

In an embodiment, a hall sensor is used in the current measuring module 140. However, those skilled in the art may use various technologies including a current transformer, a shunt resistor current meter, or the like as the current measuring module 140.

Unlike the conventional systems, the energy measuring unit 200 is configured to supply usage power of the current measuring module 140 by using power in the distribution board 10 in order to solve the problems stated in the conventional systems. Further, the energy measuring unit 200 is manufactured to be compatible with the branch circuit breaker 120 to install the energy measuring unit 200 in the distribution board 10 without an additional process such as hall processing of the distribution board 10 for inputting the electric wire, or the like.

Accordingly, the inconvenience of the installation of the energy measuring unit 200 is resolved. Additionally, the wireless communication antenna of the energy measuring unit 200 and the communication unit 240 is fixed without facing a wall of a building to solve a communication failure problem.

FIG. 2 illustrates a configuration of the energy measuring unit 200 compatible with the circuit breaker in the distribution board 10, according to embodiments as described herein.

In an embodiment, the energy measuring unit 200 includes the current measuring module 140 (see FIG. 1), the voltage measuring unit 210, the measurement unit 220, the display unit 230, a control switch unit 250 (see FIG. 3), and the communication unit 240.

In the embodiment, the voltage measuring unit 210 is configured to measure voltage input through the voltage input terminal 212 of the energy measuring unit 200. The voltage input terminal 212 is a component substantially same as the fixation end 122 of the branch circuit breaker 120 connected to the branch 131 of the busbar 130. The voltage input terminal 212 is configured to apply the voltage to the voltage measuring unit 210.

FIG. 3 illustrates formation positions of the voltage input terminal 212 and a measurement device fixing unit 214. Accordingly, unlike the conventional systems, it may be convenient to install the energy measuring unit 200 in the distribution board 10 and the busbar 130 may substitute for a power or sensing wire. Therefore, the additional components and the internal space are not required as compared with the conventional systems.

Further, the measurement device fixing unit 214 is also formed at a position corresponding to the fixation unit 124 of the branch circuit breaker 120 at a released or nonmounted position. The measurement device fixing unit 214 is configured to fix the energy measuring unit 200 together with the voltage input terminal 212.

The measurement unit 220 is configured to measure energy usage information by using a measured voltage value. The user appropriately processes required information based on the voltage value measured by the voltage measuring unit 210 to generate the energy information. Additionally, more precise energy usage information may be measured by using a current value measured by the current measuring module 140. For example, valid or invalid power consumption can be calculated based on the voltage value and the current value.

In the embodiment, the display unit 230 can be configured to display the measured energy usage information corresponding to at least a part of an exposed portion 106 previously formed on a distribution board cover 150.

FIG. 3 illustrates an external configuration of the energy measuring unit 200 compatible with the circuit breaker in the distribution board 10, according to embodiments as described herein. Formation positions of the display unit 230 and the control switch unit 250 are illustrated in the FIG. 3.

The display unit 230 is formed at a portion 105 corresponding to the exposed portion 106 formed for the switch unit 126 of the branch circuit breaker 120 on the distribution board cover 150. In the embodiment, a display device such as a Liquid Crystal Display (LCD) or the like is used as the display unit 230. However, those skilled in the art may use a Light Emitting Diode (LED) or other display devices as the display unit, in order to display a status of the energy measuring unit 200 or display a measurement result.

Accordingly, the energy usage information may be simply displayed without an external monitoring device. Further, it is possible to intuitively notify status information of the product in addition to the energy usage information.

Further, referring to the FIG. 3, in an embodiment, the control switch unit 250 is configured to be exposed through at least a part of the exposed portion 106 to receive a command for initializing the energy measuring unit 200 or perform a predetermined specific operation from the user. For example, when the status of the device needs to be initialized due to a problem such as an operational error of the energy measuring unit 200, or the like, an initialization command may be input through the control switch unit 250.

As another example of using the control switch unit 250, a switch for selecting an operation mode is implemented to set a specific operation mode of the energy measuring unit 200. Therefore, when the measurement device in the related art is installed in the distribution board 10, a disadvantage that it is difficult to operate the measurement device may be supplemented.

In an embodiment, the communication unit 240 can be configured to transmit or receive the energy usage information to or from an remote electronic device such as an external monitoring device or a server on the Internet. Further, the communication unit 240 can be configured to receive update information of the energy measuring unit 200 or a control signal for the energy measuring unit 200.

The measured energy usage information is transmitted to a user terminal in which external monitoring is available to allow the user to easily check an energy usage status. On the contrary, the specific mode or the command such as the initialization, or the like can be received from the user terminal to control an operation of the energy measuring unit 200 through the mode or command. Further, it is possible to receive data for updating internal firmware of the energy measuring unit 200, or the like and update the internal firmware or the like.

In the embodiment, the wireless communication antenna of the communication unit 240 is installed without facing the wall on which the distribution board 10 is installed. Accordingly, the wireless communication antenna is less influenced by an installation scheme of an installer or an installation direction of the wireless communication antenna depending on an internal structure of the distribution board 10.

Further, the wireless communication antenna of the communication unit 240 may be, for example, deployed at a position which does not overlap with the voltage input terminal 212 by avoiding a position of a top end of the energy measuring unit 200. In an embodiment, an arc may be generated between the fixation end 122 of the branch circuit breaker 120 (or the voltage input terminal 212 of the energy measuring unit 200) and the busbar 130. In this case, it is preferable to deploy the wireless communication antenna at a position from an arc generable area by a predetermined distance or more so as to minimize noise which may be generated in the communication unit 240 due to the arc.

The energy measuring unit 200 according to the embodiment may similarly use a fixation bolt on the top of the branch circuit breaker 120. That is, the energy measuring unit 200 is compatible with the branch circuit breaker 120. Herein, the term “compatible” non-exclusively means that the energy measuring unit 200 may be fixed by a method which is substantially the same as the method for fixing the branch circuit breaker 120 to the distribution board. For example, in a structure which is the same as a structure for fixing the top of the branch circuit breaker 120 to the distribution board.

Therefore, the energy measuring unit 200 according to an embodiment may be mounted at a position on which at least one branch circuit breaker 120 of the plurality of branch circuit breakers 120 of the distribution board 10 is released. Preferably, the released branch circuit breaker 120 is a branch circuit breaker 120 having the smallest energy consumption among the plurality of branch circuit breakers 120 and the branch circuit breaker 120 is released after an output line of the branch circuit breaker 120 is connected with a branch circuit breaker 120 having second smallest energy consumption in parallel.

That is, as the branch circuit breaker 120 is released, a circuit breaker having small power consumption is preferably selected and an output line of the corresponding circuit breaker is connected to another circuit breaker having small power consumption in parallel and thereafter, the branch circuit breaker 120 which is unnecessary is removed. In this case, current of the output line connected in parallel is preferably set so as not to exceed an allowance of the branch circuit breaker 120.

In an embodiment, the energy measuring unit 200 described herein can communicate with the external monitoring device and can be easily installed in the distribution board 10 without securing an additional internal space or additional wiring in the distribution board 10. In particular, fixation is easier than the conventional power measuring device and wiring is simplified by using the busbar of the conventional distribution board for power connection.

The figures illustrate a limited overview of the energy measuring unit 200 compatible with a circuit breaker in a distribution board 10 for measuring energy usage information but, it is to be understood that other embodiments are not limited thereto. The labels provided to each unit or component is only for illustrative purpose and does not limit the scope of the invention. Further, the one or more units can be combined or separated to perform the similar or substantially similar functionalities without departing from the scope of the invention. Furthermore, the energy measuring unit 200 can include various other components interacting locally or remotely along with other hardware or software components to measure energy usage information. For example, the component can be, but is not limited to, a process running in the controller or processor, an object, an executable process, a thread of execution, a program, or a computer.

The embodiments disclosed herein can be implemented through at least one software component running on at least one hardware device and performing network management functions to control the elements. The FIGS. 1 to 3 include blocks which can be at least one of a hardware device or a combination of hardware device and software component.

The foregoing description of the specific embodiments will so fully reveal the general nature of the embodiments herein that others can, by applying current knowledge, readily modify or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the technical spirit and scope of the embodiments as described herein.

What is claimed is:

1. An energy measuring unit for measuring energy usage information, the energy measuring unit comprising:
a voltage input terminal;
a voltage measuring unit electrically, connected to said voltage input terminal, configured to measure a voltage value, wherein said energy measuring unit measures said energy usage information using said voltage value; and
a communication unit configured to communicate said energy usage information to a remote electronic device;
wherein said voltage input terminal is configured to fix said energy measuring unit to a distribution board to receive voltage from a busbar of said distribution board, wherein said energy measuring unit is configured to be compatible with a branch circuit breaker coupled with said busbar of said distribution board.

2. The energy measuring unit of claim 1, wherein said energy measuring unit further comprises a current measuring module, connected to said energy measuring unit, configured to measure a current value, wherein said energy measuring unit is configured to measure said energy usage information using said voltage value and said current value.

3. The energy measuring unit of claim 1, wherein said energy measuring unit further comprises a display unit configured to display at least one of said voltage value, said current value, said energy usage information and a status of said energy measuring unit.

4. The energy measuring unit of claim 3, wherein said display unit corresponds to at least a part of a previously formed exposed portion of the distribution board.

5. The energy measuring unit of claim 1, wherein said energy measuring unit further comprises a control switch unit configured to control said energy measuring unit.

6. The energy measuring unit of claim 5, wherein said control switch unit corresponds to at least a part of a previously formed exposed portion of said distribution board.

7. The energy measuring unit of claim 1, wherein said communication unit includes a wireless communication antenna.

8. The energy measuring unit of claim 7, wherein said wireless communication antenna is installed without facing a wall on which said distribution board is installed.

9. The energy measuring unit of claim 8, wherein said wireless communication antenna is deployed in said energy measuring unit to avoid an influence of generation of an arc between said branch circuit breaker and said busbar.

10. The energy measuring unit of claim 1, wherein said energy measuring unit has substantially same width as said branch circuit breaker.

11. A distribution board for supplying electricity to household, the distribution board comprising:
a main circuit breaker configured to cut off an electricity input in said household;
a branch circuit breaker receiving electricity from said main circuit breaker to supply said electricity to a branch;
a busbar electrically connecting said main circuit breaker and said branch circuit breaker;
a distribution board cover protecting said distribution board; and
an energy measuring unit configured to measure energy consumption supplied to said distribution board, wherein said energy measuring unit comprises:
a voltage input terminal;
a voltage measuring unit, electrically connected with said voltage input terminal, to measure a voltage value;
an energy measuring unit configured to measure energy usage information using said voltage value; and
a communication unit configured to communicate said energy usage information to a remote electronic device,
wherein said voltage input terminal is configured to fix said energy measuring unit to said distribution board to receive voltage from said busbar, wherein said energy measuring unit is configured to be compatible with said branch circuit breaker coupled with said busbar of said distribution board.

12. The distribution board of claim 11, wherein said energy measuring unit is installed at a position having smallest energy consumption among positions at which said branch circuit breaker is installed.

13. The distribution board of claim 12, wherein an outline of said busbar is connected to a branch circuit breaker having second energy consumption in parallel.

14. The distribution board of claim 11, wherein said distribution board further comprises a control switch unit configured to control said energy measuring unit.

15. The distribution board of claim 14, wherein said control switch unit corresponds to at least a part of a previously formed exposed portion of said distribution board.

16. The distribution board of claim 11, wherein said communication unit comprises a wireless communication antenna.

17. The distribution board of claim 16, wherein said wireless communication antenna is installed without facing a wall on which said distribution board is installed.

18. The distribution board of claim 17, wherein said wireless communication antenna is deployed in said energy measuring unit to avoid an influence of generation of an arc between said branch circuit breaker and said busbar.

19. The distribution board of claim 11, wherein said energy measuring unit has substantially same width as said branch circuit breaker.
